(19) United States
(12) Patent Application Publication
(10) Pub. No.: US 2004/0152239 A1
(43) Pub. Date: Aug. 5, 2004

(54) Interface improvement by electron beam process

(75) Inventors: Tien-I Bao, Hsin-Chu (TW); Syun-Ming Jang, Hsin-Chu (TW)

Correspondence Address: DUANE MORRIS, LLP, IP DEPARTMENT, ONE LIBERTY PLACE, PHILADELPHIA, PA, 19103-7396, US

(73) Assignee: Taiwan Semiconductor manufacturing Co., Ltd.

(21) Appl. No.: 10/348,447

(22) Filed: Jan. 21, 2003

(51) Int. Cl. H01L 21/44

(52) U.S. Cl. 438/118

(57) ABSTRACT

A process for bonding layers within a semiconductor device includes the steps of: (a) applying a first dielectric layer above a substrate, (b) applying a second dielectric layer on the first dielectric layer, and (c) exposing the dielectric layers to electron beam irradiation under conditions sufficient to cure the second dielectric layer and cure at least a portion of the first dielectric layer adjacent to the second dielectric layer. The interface adhesion is thus increased between the first dielectric layer and the second dielectric layer. Similarly, electron beam irradiation can be used to increase the interface adhesion between a dielectric layer and a metal layer formed on the dielectric layer, or to increase the interface adhesion between a metal layer and a dielectric layer formed on the metal layer.

### FIELD OF THE INVENTION

The present invention relates to semiconductor fabrication techniques generally, and inter-layer interface bonding in particular.

### BACKGROUND

In conventional integrated circuits, a plurality of dielectric and metal layers are applied to a semiconductor substrate (e.g., silicon, GaAs, or the like). For example, a dual damascene process may be used to form an integrated circuit having copper conductors. An oxide layer is deposited over the substrate by chemical vapor deposition (CVD). A thin etch stop layer, such as Silicon Nitride (SiN), is formed on the oxide layer. A thin dielectric layer is formed on the etch stop layer. Holes (vias) are formed in the oxide layer above conductor regions (e.g., source and drain) in the substrate, and trenches are etched in the oxide layer. Then a layer of metal is deposited on the oxide layer to fill the vias and trenches. Excess metal is removed using chemical mechanical polishing (CMP), for example. Additional dielectric and metal layers are deposited and processed.

Poor interface adhesion between two consecutive dielectric layers or between adjacent metal and dielectric layers results in delamination and peeling during chemical mechanical polishing (CMP) and packaging.

In the prior art, pre-deposition treatments have been used in attempts to improve interface adhesion and prevent delamination. Examples of such pre-treatments include applying heat only or plasmas or chemical dipping. However, these types of pre-treatments usually damage the integrated circuit materials.

An improved inter-layer interface is desired.

### SUMMARY OF THE INVENTION

A process for bonding layers within a semiconductor device includes the steps of: (a) applying a first dielectric layer above a substrate, (b) applying a second dielectric layer on the first dielectric layer, and (c) exposing the dielectric layers to electron beam irradiation under conditions sufficient to cure the second dielectric layer and cure at least a portion of the first dielectric layer adjacent to the second dielectric layer. The interface adhesion is thus increased between the first dielectric layer and the second dielectric layer.

Another process for bonding layers within a semiconductor device includes: (a) applying a first layer onto a substrate, the first layer being formed from one of the group consisting of a dielectric material and a metal, (b) applying a second layer on the first layer, the second layer being formed from the other of the group consisting of the dielectric material and the metal, and (c) exposing the layers to electron beam irradiation under conditions sufficient to cure at least a portion of the dielectric layer at the interface between the dielectric and metal layers. The interface adhesion is thus increased between the dielectric layer and the metal layer.

### BRIEF DESCRIPTION OF THE DRAWINGS

FIGS. 1A-1C show an exemplary method for forming an improved interface between layers in an integrated circuit.

FIGS. 2A-2C show a variation of the method of FIGS. 1A-1C.

FIGS. 3A-3C show another variation of the method of FIGS. 1A-1C.

FIGS. 4A-4F show a further variation of the method of FIGS. 1A-1C.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

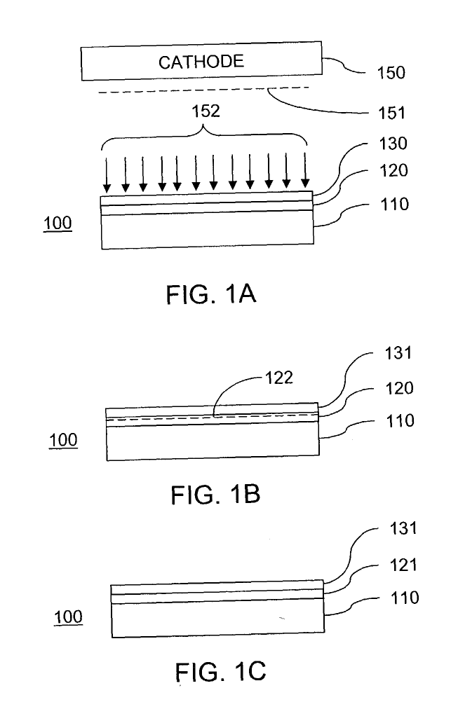

FIGS. 1A-1C show an exemplary process for improving the bonding of layers within an integrated circuit 100. As shown in FIG. 1A, the integrated circuit includes a substrate 110, with a first layer 120 and a second layer 130 formed above the substrate.

For the purpose of the examples described herein, the term “substrate” 110 may refer to a bare substrate of semiconductor material (e.g., gallium arsenide (GaAs), germanium, silicon, silicon germanium, lithium niobate and compositions containing silicon such as crystalline silicon, polysilicon, amorphous silicon, epitaxial silicon, and silicon dioxide (SiO₂) and mixtures thereof) having a plurality of doped regions (not shown) defining conductors. The term “substrate” 110 as used herein may also refer to a piece of a semiconductor material having any number of layers formed thereon (e.g., dielectric layers, metal layers, etch stop layers, barrier layers, or the like). FIGS. 1A-1C are primarily focused on the top two layers 120 and 130 and the interface therebetween. These layers 120 and 130 may be disposed on a bare substrate 110, or on top of any intermediate layers (e.g., etch stop, barrier, intermetal dielectric, metal or combination thereof, or the like) formed on the bare substrate. For example, the top surface of “substrate 110” may include a combination of Copper lines and low dielectric constant IMD material formed by a damascene process (and the associated CMP).

For the purpose of the examples described herein, the term “layer” can be, but is not limited to, a continuous layer that covers the entire surface area of the integrated circuit. A layer may be discontinuous, and may have holes (vias) therethrough or trenches therein. A layer may only include lines and/or pads that occupy a relatively small fraction of the total area of the integrated circuit.

In some embodiments, the first layer 120 is a first dielectric layer, applied above the substrate 110, and the second layer 130 is a second dielectric layer applied on the first dielectric layer. Exemplary dielectric materials for layer 120 or 130 include, but are not limited to, silicon containing spin-on glasses, i.e. silicon containing polymer such as an alkoxysilane polymer, a silsesquioxane polymer, a siloxane polymer; a poly(arylene ether), a fluorinated poly(arylene ether), other polymeric dielectric materials, nanoporous silica or mixtures thereof. Other exemplary dielectrics for layer 120 or 130 include polymeric dielectric materials such as an nanoporous silica alkoxysilane polymer formed from an alkoxysilane monomer, such as tetraethoxysilane (TEOS). Also useful are hydrogensiloxanes, hydrogensilsesquioxanes, and hydroorganosiloxanes. Exemplary polymers include but are not limited to hydrogensiloxane, hydrogensilsesquioxane, hydrogenmethylsiloxane, hydrogenethylsiloxane, hydrogenpropylsiloxane, hydrogenbutylsiloxane, hydrogentert-butylsiloxane, hydrogenphenylsiloxane, hydrogenmethylsilsesquioxane, hydrogenethylsilsesquioxane, hydrogenpropylsilsesquioxane, hydrogenbutylsilsesquioxane, hydrogentert-butylsilsesquioxane and hydrogenphenylsilsesquioxane and mixtures thereof. Exemplary organic polymers for layers 120 and 130 include polyimides, fluorinated and nonfluorinated polymers, in particular fluorinated and nonfluorinated poly(arylethers), and copolymer mixtures thereof. Any suitable technique may be used for the deposition of these layers 120 and 130.

As shown in FIG. 1A, the dielectric layers 120 and 130 are exposed to electron beam irradiation 152 under conditions sufficient to cure the second dielectric layer and cure at least an upper portion of the first dielectric layer (i.e., the portion adjacent to the second dielectric layer). During the exposure, the topmost layer 130 is directly exposed to the electron beam irradiation, and the lower layer 120 is exposed by way of the portion of the radiation that penetrates all the way through the top layer.

The electron beam irradiation may be formed by a cold cathode gas discharge electron source 150, such as any of those referenced or described in U.S. Pat. No. 5,003,178, which is incorporated by reference herein in its entirety. For example, the electron source may include a glow discharge cathode 150 and an intermediate grid anode 151 between the cathode and the dielectric layers 130, 120. Other suitable electron beam sources may alternatively be used, in accordance with the electron energy, flux and dos ranges described below.

The level and duration of the irradiation may be any of the types referenced or described in U.S. Pat. No. 6,207,555 B1, which is incorporated by reference herein in its entirety. For example, the electron beam may have an energy level between about 1 KeV and about 60 KeV, and the electron beam may provide an electron dose between about 10 μC/cm² and about 50,000 μC/cm². In some embodiments, the electron beam has an energy level between about 1 KeV and about 30 KeV, and the electron beam provides an electron dose between about 50 μC/cm² and about 50,000 μC/cm².

FIG. 1B shows one exemplary configuration 100 after the electron beam irradiation is applied. The second dielectric layer 131 is completely cured. At least an upper portion 122 of the first dielectric layer 120 is also cured, so that the material in the interface between the layers 120 and 130 is cured. The thickness of the cured portion 122 may be very thin, so long as changes occur at the interface. This curing of material in the interface region increases interface adhesion between the first dielectric layer 120 and the second dielectric layer 130. In FIG. 1B, a lower portion of the first dielectric layer 120 (i.e., the portion distal from the second dielectric layer) is substantially not cured by the electron beam irradiation 152.

FIG. 1C shows another exemplary configuration 100 after the electron beam irradiation is applied. Both the first dielectric layer 121 and the second dielectric layer 131 are completely cured by the electron beam irradiation, including the lower portion of the first dielectric layer. This curing of material increases bonding density, and thus increases interface adhesion between the first dielectric layer 121 and the second dielectric layer 131.

Although FIG. 1B shows only a very thin upper layer 122 of the first dielectric layer 120 being cured by the electron beam irradiation, and FIG. 1C shows a completely cured first dielectric layer 121, the depth of the curing of the first dielectric layer can be anywhere between these two extremes. Thus, the exemplary processes of FIGS. 1B and 1C provide a wide degree of freedom in terms of the energy level and dosage that produce improved interface bonding results.

In one example according to FIGS. 1A and 1B (or FIGS. 1A and 1C), one of the first and second dielectric layers 120, 130 is an etch stop layer, and the other of the first and second dielectric layers has a relatively low dielectric constant. The etch stop layer can be either the bottom one or the top one of the two layers.

For example, the layer having the relatively low dielectric constant may be formed (by CVD or Spin-on) from an SiOC:H material or an organic material, and may have a thickness between about 1,000 Angstroms (Å) and about 10,000 Å.

The etch stop layer may be formed from SiN, SiCO and SiCN, or other suitable etch stop material. The etch stop layer may have a thickness between about 100 Å and about 1,000 Å.

In another example according to FIGS. 1A and 1B (or 1A and 1C), the first dielectric layer 120 has a relatively low dielectric constant, and the second dielectric layer 130 is an anti-reflection layer. For example, the anti-reflection layer may be an SiON layer having a thickness between about 100 Å and about 5,000 Å.

These are only examples, and other combinations of dielectric layers, including materials with different dielectric constants, barrier layers, etch stop layers, reflective or anti-reflection layers or the like are also contemplated.

Although the examples described above include two layers 120 and 130 formed of dielectric materials, either of the first and second layers 120, 130 may be a metal layer. For example, in FIG. 1A, a first layer 120 formed from one of the group consisting of a dielectric material and a metal may be applied onto a substrate 110, followed by a second layer 130 formed on the first layer, where the second layer is formed from the other of the group consisting of the dielectric material and the metal. Examples of suitable metal layers include, but are not limited to, titanium nitride, tantalum nitride, aluminum, aluminum alloys, copper, copper alloys, tantalum, and tungsten.

Subsequently, the layers 120, 130 are exposed to the electron beam irradiation 152 under conditions sufficient to cure at least a portion of the dielectric layer at the interface between the dielectric and metal layers, thereby increasing interface adhesion between the dielectric layer and the metal layer.

For example, the first layer 120 may be formed from a material having a relatively low dielectric constant, and the second layer may be formed of 300 Å of TaN. The electron beam irradiation may be similar to that described above. That is, the electron beam may have an energy level between about 1 KeV and about 60 KeV, wherein the electron beam provides an electron dose between about 10 μC/cm² and about 50,000 μC/cm².

In another example, the first layer 120 is formed from copper, and the second layer 130 is an etch stop layer such as SiN, SiCO and SiCN, or other suitable etch stop material. The etch stop layer may have a thickness between about 100 Å and about 1,000 Å. The electron beam irradiation treatment may be the same as, or similar to, that described above.

In an experiment including a first layer of 500 Å of SiCO and a second layer of 5000 Å SiOC:H, the interface adhesion after electron beam treatment was measured at 4.5 Gpa using a 4 point bend test. Without the electron beam treatment, the interface adhesion for an otherwise similar configuration was 2.5 Gpa.

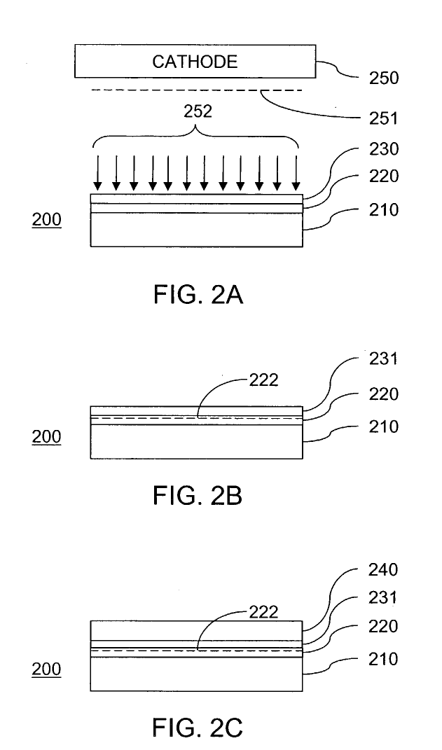

FIGS. 2A-2C show another exemplary embodiment. Items in FIGS. 2A-2C that are the same as items in FIGS. 1A-1C are indicated by reference numerals that are increased by 100. These include assembly 200, substrate 210, first layer 220, upper portion 222 of first layer, second layer 230, cured second layer 231, cathode 250, grid 251 and irradiation 252. Detailed descriptions of each of these items are not repeated. As described above with reference to FIGS. 1A-1C, substrate 210 may be a bare semiconductor material, or a semiconductor material having one or more lower layers (not shown separately) deposited thereon.

FIGS. 2A and 2B show a configuration 200 similar to that shown in FIGS. 1A and 1B. The first layer 220 and second layer 230 are applied to the substrate 210, and the layers are exposed to irradiation 252, sufficiently to cure the interface between the first layer 220 and second layer 230. Thus, a cured second layer 231 and a cured upper portion 222 of the first layer 220 are formed.

FIG. 2C shows a third layer 240 applied on the cured second layer 231 after the electron beam irradiation step. In some embodiments, the third layer 240 is formed of the same material as the second layer 231. For example, the second and third layers 231 and 240 may be formed of the same dielectric material. The third layer may have any desired thickness, including, but not limited to, thicknesses which are too great for the electron beam 252 to penetrate the third layer if the same energy level and dosage of FIGS. 1A and 2A are used. By depositing a relatively thin second layer 230 and exposing the second layer to the beam 252 before the third layer 240 is applied, bonding strength between the first layer 220 and second layer 230 can be increased, even where the combined thickness of the second and third layers 230, 240 is too great for penetration of the beam. Thus, in a configuration having a need for an “upper layer” (on top of the first layer 220) that is too thick for the beam 252 to penetrate all the way to the interface, the “upper layer” can be split into two layers 230 and 240 of the same material, the first of which is deposited before the electron beam treatment, and the second of which is deposited after the electron beam treatment. This technique is advantageous where the material of the layers 230 and 240 has a good cohesion at the interface between the layers 230 and 240, but improvement in the adhesion between layers 220 and 230 is desired.

Note that there is no requirement for the layer 240 to have any minimum thickness. This technique can be used regardless of how large or small layer 240 is (but the technique is most advantageous where the combined thickness of the layers 230 and 240 is too thick for the beam 252 to penetrate completely to cure the interface material). Nevertheless, one of ordinary skill will understand that, if the total thickness of the material to be formed on top of the first layer 120 is sufficiently thin so that at least an upper portion 122 of the first layer 120 is cured, then it is advantageous to use the technique of FIGS. 1A and 1B, instead of splitting the upper material into two layers deposited separately as in FIGS. 2A-2C. This is because the technique of FIGS. 1A-1B involves deposition of one fewer layer than that of FIGS. 2A-2C, and is thus quicker and less expensive.

One of ordinary skill will understand that a desirable thickness for the second layer 230 depends on the type of material, because different materials have different reflectivity and absorptance for the electron beam irradiation. For example, if the second layer 230 is made of SiN, SiCN, SiCO, SiON, then a desirable thickness for the second layer is between about 5 Å and 500 Å. If the second layer 230 is made of an SiOC:H material having a low dielectric constant, then a desirable thickness for the second layer is between about 500 Å and 2000 Å.

Given any other type of material for the second layer 230, one of ordinary skill can readily determine a desirable thickness for the second layer 230. For example, a desired thickness can be found by testing an amount of electron beam irradiation that can penetrate several layers of respectively different thicknesses and selecting the maximum tested thickness at which the energy penetrating the material has a threshold intensity level. Alternatively, a desired thickness can be found by testing several assemblies 200 having respectively different second layer thickness, and selecting the maximum thickness tested at which the bond strength has a threshold adhesion level (e.g., as measured by 4 point bend test).

Once the thickness of layer 230 is determined, the thickness of the layer 240 is readily determined by subtracting the thickness of layer 230 from the total desired thickness of the given material.

In other embodiments, layer 240 can include one or more layers of different materials from the material of layer 230. In other words, once the electron beam irradiation is applied to the layers 220 and 230 in FIG. 2A, any number of additional processes may be performed, and additional layers added. Layer 230 need not be the last layer deposited on the integrated circuit 200.

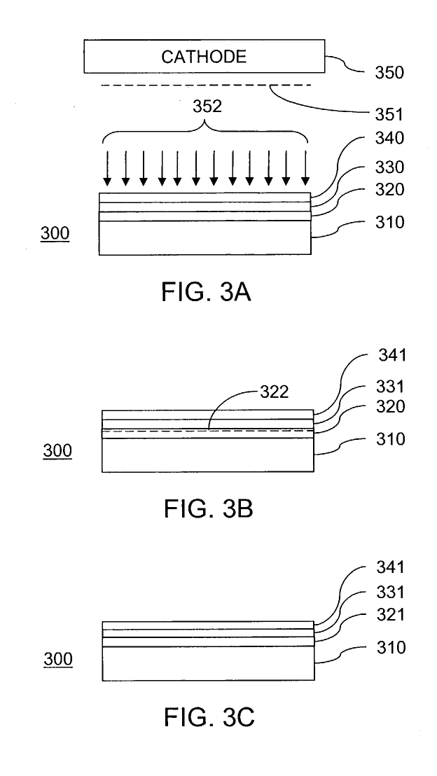

FIGS. 3A-3C show a configuration 300 having bottom layers similar to that shown in FIGS. 1A and 1B, with like items indicated by reference numerals that are increased by 200 from the reference numerals of FIGS. 1A and 1B. The first layer 320 and second layer 330 are applied to the substrate 310. In addition, a third layer 340 is deposited on the second layer 330 before application of the electron beam 352. The third layer 340 may be formed of a different material than the second layer 330.

As shown in FIG. 3A, the layers 320, 330, 340 are exposed to irradiation 352, sufficiently to cure the second and third layers 330 and 340, respectively, and the interface between the first layer 320 and second layer 330.

Thus, as shown in FIG. 3B, a cured second layer 331 a cured third layer 341 and at least a cured upper portion 322 of the first layer 320 are formed. This technique simultaneously increases interface adhesion between the second layer 330 and the third layer 340, and increases interface adhesion between the first layer 320 and the second layer 330. In FIG. 3B, a lower portion of the first dielectric layer 320 is substantially not cured by the electron beam irradiation.

FIG. 3C shows another exemplary configuration 300 after the electron beam irradiation 352 is applied, wherein a lower portion of the first dielectric layer 321 is cured by the electron beam irradiation. The first dielectric layer 321, the second dielectric layer 331 and the third dielectric layer 341 are completely cured by the electron beam irradiation, including the lower portion of the first dielectric layer 321. This curing of material increases bonding density, and thus increases interface adhesion between the first dielectric layer 321 and the second dielectric layer 331 and between the second dielectric layer 331 and the third dielectric layer 341.

Although FIG. 3B shows only a very thin upper layer 322 of the first dielectric layer 320 being cured by the electron beam irradiation, and FIG. 3C shows a completely cured first dielectric layer 321, the depth of the curing of the first dielectric layer can be anywhere between these two extremes.

One of ordinary skill understands that FIGS. 3A-3C may be generalized to even larger numbers of layers. If the upper layers are sufficiently thin, then the electron beam irradiation can be applied to cure three, four, five or more inter-layer interfaces simultaneously, to improve bond adhesion.

An exemplary configuration according to FIGS. 3A-3C includes a first dielectric layer 320 (321) formed of 500 Å of SiCO, a second dielectric layer 330 (331) formed of 5,000 Å of a material having a relatively low dielectric constant, and a third dielectric layer 340 (341) formed of 1,200 Å of SiON. The electron beam 352 may have an energy of 1 to 60 KeV, and a dose between about 10 μC/cm² and 50000 μC/cm².

In another exemplary configuration according to FIGS. 3A-3C, the first dielectric layer is an etch stop layer, the second dielectric layer is formed of a material having a relatively low dielectric constant, and the third dielectric layer an anti-reflection layer.

These are only examples, and are not intended to limit the application of the techniques of FIGS. 3A-3C.

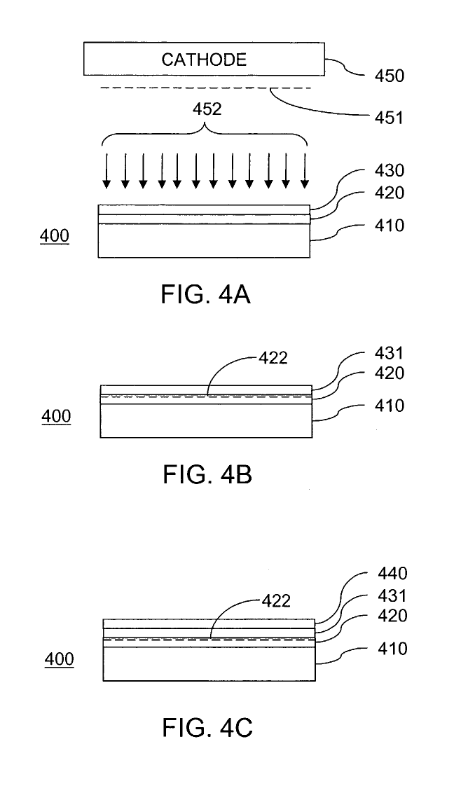

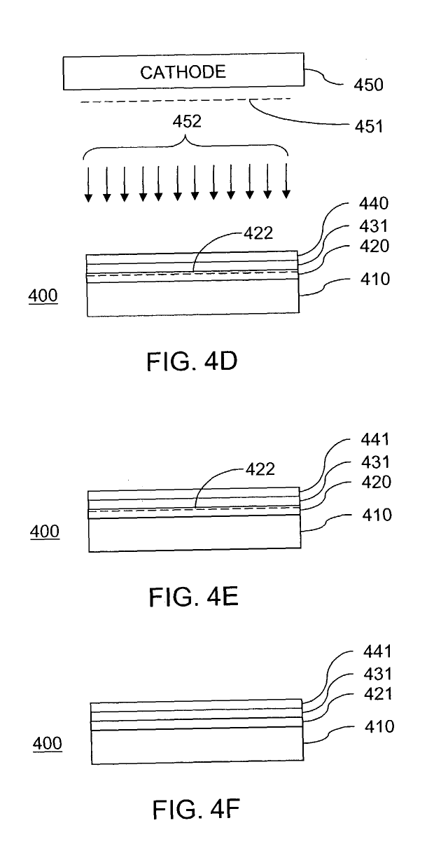

FIGS. 4A-4E show another example. FIGS. 4A and 4B show a configuration 400 similar to that shown in FIGS. 2A and 2B, wherein like items have reference numerals increased by 200 from the reference numerals of FIGS. 2A and 2B. The first layer 420 and second layer 430 are applied to the substrate 410, and the layers are exposed to irradiation 452, sufficiently to cure the interface between the first layer 420 and second layer 430. Thus, a cured second layer 431 and a cured upper portion 422 of the first layer 420 are formed.

FIG. 4C shows a third layer 440 applied on the cured second layer 431 after the electron beam irradiation step if FIG. 4A. In some embodiments, the third layer 440 is formed of the same material as the second layer 431. In FIG. 4C, the third layer 440 is sufficiently thin so that a subsequent electron beam irradiation treatment can penetrate layer 440 and cure the interface between the cured layer 431 and layer 440. (By comparison, the third layer 240 in FIG. 2C could optionally be of a thickness so large that an electron beam treatment could not penetrate layer 240.)

FIG. 4D shows a second electron beam irradiation treatment being applied to the layers of assembly 400. This treatment exposes the dielectric layers 431 and 440 to electron beam irradiation under conditions sufficient to cure the third dielectric layer 440 and an interface between the second dielectric layer 431 and the third dielectric layer, thereby increasing interface adhesion between the second dielectric layer and the third dielectric layer.

FIG. 4E shows an example of a resulting configuration, having a cured third layer 441, a cured second layer 431, and a cured upper portion 422 of the first layer 420.

In one example of a structure 400 according to FIGS. 4A-4D, the first dielectric layer 420 is an etch stop layer, the second dielectric layer 430 is formed of a material having a relatively low dielectric constant, and the third dielectric layer 440 is an anti-reflection layer.

FIG. 4F shows another possible configuration resulting from the steps of FIGS. 4A-4D. In FIG. 4F, the first layer 420 and second layer 430 are completely cured (by the first electron beam treatment (FIG. 4A) to form cured layers 421 and 431 (corresponding to the situation where the dashed line in FIGS. 4B-4D coincides with the bottom of layer 420). Then the third layer 430 is applied, and a second electron beam treatment is performed, to improve the adhesion at the interface between layers 431 and 440. Thus, FIG. 4F achieves a result similar to that of FIG. 3C, wherein three layers 321, 331 and 341 are completely cured. However, the method of FIGS. 4A-4D and 4F allows the electron beam treatment to be used to improve adhesion between a series of three or more layers, so long as the electron beam treatment at each stage is sufficient to penetrate the topmost layer (at the time of the treatment) and the interface immediately below the topmost layer. It is not necessary for that the combination of all of the layers together permit penetration of the electron beam. Further, the steps of depositing an additional layer and repeating the electron beam irradiation can be reiterated as many times as desired to improve the adhesion of succeeding layers, regardless of the total combined thickness of all of the layers.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A process for bonding layers within a semiconductor device, comprising the steps of:
(a) applying a first dielectric layer above a substrate;
(b) applying a second dielectric layer on the first dielectric layer;
(c) exposing the dielectric layers to electron beam irradiation under conditions sufficient to cure the second dielectric layer and cure at least a portion of the first dielectric layer adjacent to the second dielectric layer, thereby increasing interface adhesion between the first dielectric layer and the second dielectric layer.

2. The process of claim 1, wherein a portion of the first dielectric layer distal from the second dielectric layer is substantially not cured by the electron beam irradiation.

3. The process of claim 1, wherein a lower portion of the first dielectric layer is cured by the electron beam irradiation.

4. The process of claim 1, wherein one of the first and second dielectric layers is an etch stop layer, and the other of the first and second dielectric layers has a relatively low dielectric constant.

5. The process of claim 4, wherein the layer having the relatively low dielectric constant is formed from one of the group consisting of an SiOC:H material and an organic material, and has a thickness between about 1,000 Å and about 10,000 Å.

6. The process of claim 4, wherein the etch stop layer is formed from one of the group consisting of SiN, SiCO and SiCN, the etch stop layer having a thickness between about 100 Å and about 1,000 Å.

7. The process of claim 1, wherein the first dielectric layer has a relatively low dielectric constant, and second dielectric layer is an anti-reflection layer.

8. The process of claim 7, wherein the anti-reflection layer is an SiON layer having a thickness between about 100 Å and about 5,000 Å.

9. The process of claim 1, wherein the electron beam has an energy level between about 1 KeV and about 60 KeV.

10. The process of claim 1, wherein the electron beam provides an electron dose between about 10 μC/cm² and about 50,000 μC/cm².

11. The process of claim 1, further comprising:
(d) applying a third dielectric layer on the second dielectric layer after step (c), the third dielectric layer being formed of the same material as the second dielectric layer.

12. The process of claim 11, wherein a combined thickness of the second and third layers is too thick to completely cure the second and third layers if the second and third layers are exposed to electron beam irradiation having the same energy level and dose as applied to the second layer in step (c).

13. The process of claim 12, wherein the second dielectric layer has a thickness between about 5 Å and about 500 Å.

14. The process of claim 12, wherein the third dielectric layer has a thickness between about 500 Å and about 10,000 Å.

15. The process of claim 12, wherein the second dielectric layer is one of the group consisting of SiN, SiCN, SiCO, SiON.

16. The process of claim 12, wherein the second dielectric layer has a thickness between about 500 Å and about 2,000 Å.

17. The process of claim 16, wherein the second dielectric layer is formed of an SiOC:H material.

18. The process of claim 1, further comprising
(d) applying a third dielectric layer on the second dielectric layer before step (c),
wherein step (c) includes exposing the dielectric layers to electron beam irradiation under conditions sufficient to cure the third dielectric layer, the second dielectric layer and at least the portion of the first dielectric layer adjacent to the second dielectric layer, thereby increasing interface adhesion between the second dielectric layer and the third dielectric layer and increasing interface adhesion between the first dielectric layer and the second dielectric layer.

19. The process of claim 18, wherein a lower portion of the first dielectric layer is substantially not cured by the electron beam irradiation.

20. The process of claim 18, wherein a lower portion of the first dielectric layer is cured by the electron beam irradiation.

21. The process of claim 18, wherein:
the first dielectric layer is formed of 500 Å of SiCO,
the second dielectric layer is formed of 5,000 Å of a material having a relatively low dielectric constant, and
the third dielectric layer is formed of 1,200 Å of SiON.

22. The process of claim 18, wherein:
the first dielectric layer is an etch stop layer,
the second dielectric layer is formed of a material having a relatively low dielectric constant, and
the third dielectric layer an anti-reflection layer.

23. The process of claim 1, further comprising:
(d) applying a third dielectric layer on the second dielectric layer after step (c); and
(e) exposing the dielectric layers to electron beam irradiation under conditions sufficient to cure the third dielectric layer and an interface between the second dielectric layer and the third dielectric layer, thereby increasing interface adhesion between the second dielectric layer and the third dielectric layer.

24. The process of claim 23, wherein:
the first dielectric layer is an etch stop layer,
the second dielectric layer is formed of a material having a relatively low dielectric constant, and
the third dielectric layer an anti-reflection layer.

25. The process of claim 1, wherein the substrate is one of the group consisting of Si and GaAs.

26. The process of claim 1, wherein the electron beam irradiation is formed by a cold cathode gas discharge electron source.

27. The process of claim 1, wherein the electron beam irradiation is formed by an electron source having a glow discharge cathode and an intermediate grid anode between the cathode and the dielectric layers.

28. A process for bonding layers within a semiconductor device, comprising the steps of:
(a) applying a first layer above a substrate, the first layer being formed from one of the group consisting of a dielectric material and a metal;
(b) applying a second layer on the first layer, the second layer being formed from the other of the group consisting of the dielectric material and the metal;
(c) exposing the layers to electron beam irradiation under conditions sufficient to cure at least a portion of the dielectric layer at the interface between the dielectric and metal layers, thereby increasing interface adhesion between the dielectric layer and the metal layer.

29. The process of claim 28, wherein:
the first layer is formed from a material having a relatively low dielectric constant, and
the second layer is formed of TaN.

30. The process of claim 28, wherein:
the first layer is formed from copper, and
the second layer is an etch stop layer.

31. The process of claim 28, wherein the electron beam has an energy level between about 1 KeV and about 60 KeV.

32. The process of claim 28, wherein the electron beam provides an electron dose between about 10 μC/cm² and about 50,000 μC/cm².

33. An integrated circuit, comprising:
a substrate;
a first dielectric layer above the substrate; and
a second dielectric layer on the first dielectric layer,
wherein the dielectric layers have been exposed to electron beam irradiation under conditions sufficient to cure the second dielectric layer and cure at least a portion of the first dielectric layer adjacent to the second dielectric layer, whereby the integrated circuit has increased interface adhesion between the first dielectric layer and the second dielectric layer, relative to another integrated circuit having first and second dielectric layers that were not exposed to electron beam irradiation.

34. The integrated circuit of claim 33, wherein one of the first and second dielectric layers is an etch stop layer, and the other of the first and second dielectric layers has a relatively low dielectric constant.

35. The integrated circuit of claim 34, wherein the layer having the relatively low dielectric constant is formed from one of the group consisting of an SiOC:H material and an organic material, and has a thickness between about 1,000 Å and about 10,000 Å.

36. The integrated circuit of claim 34, wherein the etch stop layer is formed from one of the group consisting of SiN, SiCO and SiCN, the etch stop layer having a thickness between about 100 Å and about 1,000 Å.

37. The integrated circuit of claim 33, wherein the first dielectric layer has a relatively low dielectric constant, and second dielectric layer is an anti-reflection layer.

38. The integrated circuit of claim 37, wherein the anti-reflection layer is an SiON layer having a thickness between about 100 Å and about 5,000 Å.

39. The integrated circuit of claim 33, further comprising:
a third dielectric layer on the second dielectric layer, the third dielectric layer being formed of the same material as the second dielectric layer.

40. The integrated circuit of claim 33, further comprising:
a third dielectric layer on the second dielectric layer,
wherein the third dielectric layer has been exposed to electron beam irradiation under conditions sufficient to cure the third dielectric layer and an interface between the second dielectric layer and the third dielectric layer, thereby increasing interface adhesion between the second dielectric layer and the third dielectric layer, relative to another integrated circuit having first and second dielectric layers that are not exposed to electron beam irradiation.

41. An integrated circuit, comprising:
a substrate;
a first layer above the substrate, the first layer being formed from one of the group consisting of a dielectric material and a metal;
a second layer on the first layer, the second layer being formed from the other of the group consisting of the dielectric material and the metal;
wherein the layers have been exposed to electron beam irradiation under conditions sufficient to cure at least a portion of the dielectric layer at the interface between the dielectric and metal layers, whereby the integrated circuit has increased interface adhesion between the dielectric layer and the metal layer, relative to another integrated circuit having a dielectric layer and a metal layer that were not exposed to electron beam irradiation.
